(19) United States
(12) Patent Application Publication
(10) Pub. No.: US 2026/0282622 A1
(43) Pub. Date: Sep. 17, 2026

(54) OPTOELECTRONIC SEMICONDUCTOR DEVICE COMPRISING A FILLING MATERIAL AND METHOD FOR MANUFACTURING THE OPTOELECTRONIC SEMICONDUCTOR DEVICE

(71) Applicant: AMS-OSRAM INTERNATIONAL GMBH, Regensburg (DE)

(72) Inventors: Joern KAMPMEIER, Obertraubling (DE); Michael HUBER, Bad Abbach (DE); Helena DOBLINGER, Regensburg (DE); Thomas FILZ, Bad Abbach (DE); Jochen BRENDT, Regensburg (DE); Peter DEUTSCHER, Augsburg (DE)

(21) Appl. No.: 19/471,389

(22) PCT Filed: Feb. 8, 2024
(86) PCT No.: PCT/EP2024/053162

§ 371 Date: Oct. 1, 2025

(30) Foreign Application Priority Data
May 2, 2023 (DE) 10 2023 111 276.7

(51) Int. Cl. H10H 20/857; H10H 20/01; H10H 20/831; H10H 20/841

(52) U.S. Cl. CPC H10H 20/857; H10H 20/034; H10H 20/0364; H10H 20/8312; H10H 20/841

(57) ABSTRACT

An optoelectronic semiconductor device includes a semiconductor layer stack configured to generate electromagnetic radiation, a mirror including dielectric layers arranged over a first main surface of the stack, an opening formed in the mirror, extending from a first main surface of the mirror to a second surface of the mirror, the first main surface of the mirror being remote from the stack, a conductive layer arranged over the first main surface of the mirror, the conductive layer arranged on sidewalls of the opening, defining a void, and configured to electrically contact a portion of the semiconductor layer stack, a filling material filling the void, the filling material being different from the conductive layer, and a solder layer over the filling material and over the conductive layer, a material of the solder layer being different from the filling material, and a conductive carrier over the solder layer.

### CROSS-REFERENCE TO RELATED APPLICATIONS

This application is a national phase of International Application No. PCT/EP2024/053162 filed on Feb. 8, 2024, which claims priority to German patent application DE 10 2023 111 276.7, which was filed on May 2, 2023, the entire contents of both of which are incorporated herein by reference.

### FIELD OF THE INVENTION

The present disclosure relates to an optoelectronic semiconductor device comprising a filling material and to a method for manufacturing the optoelectronic semiconductor device.

### BACKGROUND

A light emitting diode (LED) is a light emitting device that is based on semiconductor materials. For example, an LED comprises a pn junction. When electrons and holes combine with each other in a region of the pn junction, for example, since a suitable voltage is applied, electromagnetic radiation is generated.

Generally, concepts are being developed for improving the light extraction and the performance of optoelectronic semiconductor devices.

### SUMMARY

According to embodiments, the above object is achieved by the claimed matter according to the independent claims. Further developments are defined in the dependent claims.

According to embodiments, an optoelectronic semiconductor device comprises a semiconductor layer stack configured to generate electromagnetic radiation, and a mirror comprising dielectric layers arranged over a first main surface of the semiconductor layer stack. An opening is formed in the mirror, the opening extending from a first main surface of the mirror to a second surface of the mirror, the first main surface of the mirror being remote from the semiconductor layer stack. The optoelectronic semiconductor device further comprises a conductive layer arranged over the first main surface of the mirror, the conductive layer being arranged on sidewalls of the opening, thereby defining a void, and being configured to electrically contact a portion of the semiconductor layer stack. The optoelectronic semiconductor device further comprises a filling material filling the void, the filling material being different from the conductive layer, and a solder layer over the filling material and over the conductive layer. A material of the solder layer is different from the filling material. The optoelectronic semiconductor device further comprises a conductive carrier over the solder layer.

For example, the semiconductor layer stack may comprise a first semiconductor layer of a first conductivity type, an active zone and a second semiconductor layer of a second conductivity type. The second semiconductor layer is arranged on a side facing the mirror, and the conductive layer is configured to electrically contact the first semiconductor layer.

For example, a thickness of the mirror may be larger than 500 nm. According to further examples, the thickness of the mirror may be larger than 1 μm. By way of example, the thickness of the mirror may be less than 5 μm.

By way of example, the filling material may comprise a conductive material.

According to embodiments, a surface of the filling material is flush with a main surface of the conductive layer.

The optoelectronic semiconductor device may further comprise a second current spreading layer in contact with the second semiconductor layer.

For example, a thickness of the solder layer is less than 1.5 μm. For example, even a thickness of less than 1 μm or less than 200 nm may be employed.

According to embodiments, a method of manufacturing an optoelectronic semiconductor device comprises forming a semiconductor layer stack configured to generate electromagnetic radiation, forming a mirror comprising dielectric layers over a first main surface of the semiconductor layer stack, and forming an opening in the mirror, the opening extending from a first main surface of the mirror to a second main surface of the mirror. The method further comprises forming a conductive layer over the first main surface of the mirror, the first main surface of the mirror being remote from the semiconductor layer stack, comprising forming the conductive layer over sidewalls of the opening, thereby defining a void. Additionally, the method comprises forming a filling material filling the void, the filling material being different from the conductive layer and forming a solder layer over the filling material and over the conductive layer, a material of the solder layer being different from the filling material. The method further comprises arranging a conductive carrier over the solder layer.

According to embodiments, the solder layer may be formed to have a thickness less than 1.5 μm. For example, even a thickness of less than 1 μm or less than 200 nm may be employed.

The method may further comprise planarizing a second main surface of a resulting workpiece before forming the solder layer.

According to embodiments, the conductive carrier may be arranged over the solder layer using a direct bonding method.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 Illustrates a Cross-sectional View of an Optoelectronic semiconductor device according to embodiments.

FIGS. 2A to 2F show cross-sectional views of a workpiece when manufacturing the optoelectronic semiconductor device.

FIG. 3A is a top view of the optoelectronic semiconductor device according to embodiments.

FIG. 3B is a cross-sectional view of a semiconductor device according to embodiments.

FIG. 4 summarizes a method according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g. supported by a base semiconductor foundation, and other semiconductor structures. For example, a layer of a first semiconductor material may be grown on a growth substrate of a second semiconductor material. According to further embodiments, the growth substrate may be an insulating substrate such as a sapphire substrate. Depending on the purpose of use, the semiconductor may be based on a direct or an indirect semiconductor material. Examples of semiconductor materials particularly suitable for generation of electromagnetic radiation comprise nitride-compound semiconductors, by which e.g. ultraviolet or blue light or longer wavelength light may be generated, such as GaN, InGaN, AlN, AlGaN, AlGaInN, phosphide-compound semiconductors, by which e.g. green or longer wavelength light may be generated such as GaAsP, AlGaInP, GaP, AlGaP, as well as further semiconductor materials including AlGaAs, Sic, ZnSe, GaAs, ZnO, Ga₂O₃, diamond, hexagonal BN und combinations of these materials. Further examples of semiconductor materials may as well be silicon, silicon-germanium and germanium. The stoichiometric ratio of the compound semiconductor materials may vary. In the context of the present specification, the term “semiconductor” further encompasses organic semiconductor materials.

The term “substrate” generally refers to semiconductor substrates, conductive or insulating substrates.

The term “vertical” as used in this specification intends to describe an orientation which is arranged perpendicular to the first surface of a substrate or semiconductor body.

The terms “lateral” and “horizontal” as used in this specification intends to describe an orientation parallel to a first surface of a substrate or semiconductor body. This can be for instance the surface of a wafer or a die.

As employed in this specification, the terms “coupled” and/or “electrically coupled” are not meant to mean that the elements must be directly coupled together-intervening elements may be provided between the “coupled” or “electrically coupled” elements. The term “electrically connected” may describe a low-ohmic electric connection between the elements electrically connected together.

The term “electrically connected” further comprises tunneling contacts between connected elements.

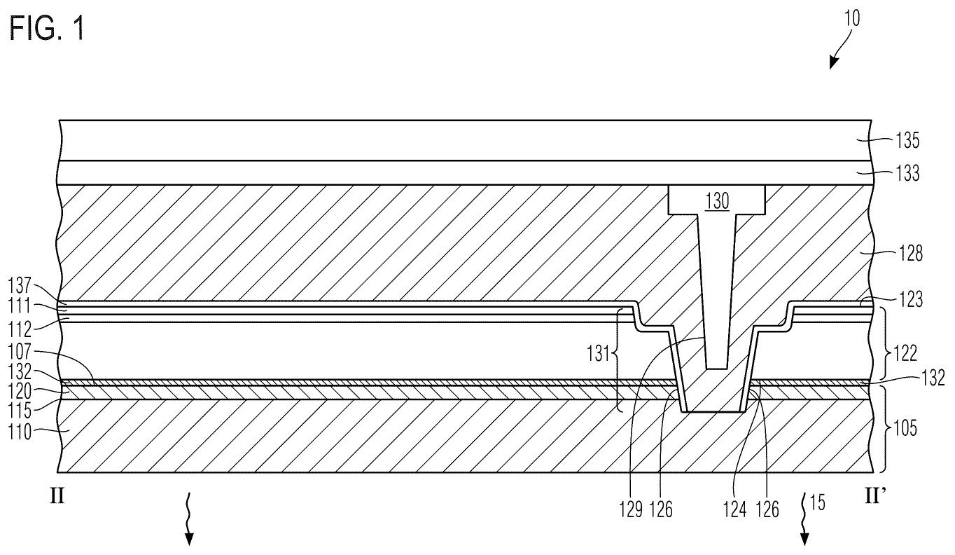

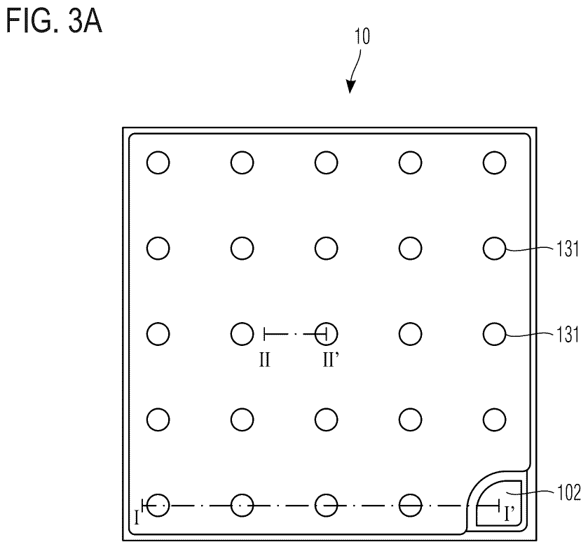

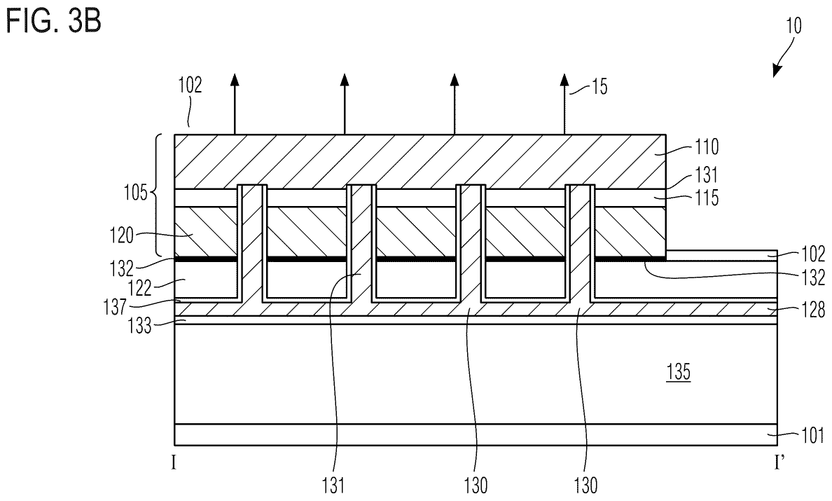

FIG. 1 is a cross-sectional view of a portion of an optoelectronic semiconductor device 10 according to embodiments. The cross-sectional view may be taken between II and II′, as is also indicated in FIG. 3A. The optoelectronic semiconductor device 10 comprises a semiconductor layer stack 105 that is configured to generate electromagnetic radiation 15. The optoelectronic semiconductor device 10 further comprises a mirror 122 which comprises dielectric layers 111, 112. For example, the dielectric layers 111, 112 may comprise SiO₂ or Nb₂O₃. The mirror 122 may further or alternatively comprise a metal layer. Examples of suitable metals of the metal layer comprise Ag, Au, Al, Pt or Rh or intermetallic compounds.

The mirror 122 is arranged over a first main surface 107 of the semiconductor layer stack 105. An opening 125 is formed in the mirror 122. The opening 125 extends from a first main surface 123 of the mirror 122 to a second surface 124 of the mirror 122. The first main surface 123 of the mirror 122 is remote from the semiconductor layer stack 105. The optoelectronic semiconductor device 10 further comprises a conductive layer 128 that is arranged over the first main surface 123 of the mirror. For example, an insulating passivation layer 137 may be arranged between the conductive layer 128 and the mirror 122.

The conductive layer 128 is arranged on sidewalls 126 of the opening 125. Thereby, a void 129 is formed. The conductive layer 128 is configured to electrically contact a portion of the semiconductor layer stack 105. The optoelectronic semiconductor device 10 further comprises a filling material 130 that fills the void 129. The filling material 130 is different from the conductive layer 128. The optoelectronic semiconductor device 10 further comprises a solder layer 133 that is arranged over the filling material 130. The solder layer 133 further is formed over the conductive layer 128. A material of the solder layer 133 is different from the filling material 130. The optoelectronic semiconductor device 10 further comprises a conductive carrier 135 that is arranged over the solder layer 133.

As employed within the present disclosure, the term “layer” also comprises a set of several sub-layers forming the layer, unless otherwise specified.

The Term “a Filling Material Being Different From the conductive layer” is intended to mean that a composition of elements constituting the conductive layer 128 is different from a composition of elements constituting the filling material 130. For example, a specific element present in the filling material may also be present in the conductive layer 128 as long as the composition ratio of this element in the filling material is different from the composition ratio of this element in the conductive layer 128. Likewise, an element present in the filling material 130 may be a component of an alloy forming the conductive layer 128 as long as the alloy of the conductive layer 128 is different from the material, e.g. a single element, a compound of this element or an alloy of this element of the filling material 130.

In a similar manner, the term “a material of the solder layer being different from the filling material” is intended to mean that a composition of elements constituting the solder layer 133 is different from a composition of elements constituting the filling material 130. For example, a specific element present in the filling material may also be present in the solder layer 133 as long as the composition ratio of this element in the filling material is different from the composition ratio of this element in the solder layer 133. Likewise, an element present in the filling material 130 may be a component of an alloy forming the solder layer 133 as long as the alloy of the solder layer 133 is different from the material, e.g. a single element, a compound of this element or an alloy of this element of the filling material 130.

For example, the semiconductor layer stack 105 may comprise a first semiconductor layer 110 of a first conductivity type, e.g. n-type, a second semiconductor layer 120 of a second conductivity type, e.g. p-type, and an active zone 115 that may be arranged between the first semiconductor layer 110 and the second semiconductor layer 120. The active zone may, for example, comprise a pn junction, a double heterostructure, a single quantum well structure (SQW, single quantum well) or a multiple quantum well structure (MQW, multi quantum well) for generating radiation. The term “quantum well structure” s does not imply any particular meaning here with regard to the dimensionality of the quantization. Therefore it includes, among other things, quantum wells, quantum wires and quantum dots as well as any combination of these layers.

According to implementations, a second current spreading layer 132 may be arranged in contact with the second semiconductor layer 120. For example, the second current spreading layer 132 may comprise a conductive material, for example, a transparent conductive oxide such as ITO (“indium tin oxide”). Due to the presence of the second current spreading layer 132, the current distribution and thus, a brightness of light emission may be made more uniform. The dielectric layers that are a component of the mirror 122 may implement a DBR layer. For example, the mirror 122 may comprise an alternating sequence of dielectric layers having comparably high and low refractive indices. The alternating sequence of layers may form a DBR (“distributed Bragg reflector”) mirror. A layer thickness may be λ/4, wherein λ denotes the wavelength of emitted electromagnetic radiation in the respective medium. A dielectric mirror may comprise, for example, 2 to 50 dielectric layers. Typically, a thickness of the single layers may be 30 to 90 nm, e.g. approximately 50 nm. The mirror 122 may for example comprise one or two or more layers having a thickness greater than 180 nm, for example, greater than 200 nm. Accordingly, the dielectric layers of the mirror 122 may be insulating and may have a high reflectivity. When the mirror 122 additionally comprises metal layer, these metal layers may be electrically connected to the second current spreading layer 132.

For example, the conductive layer 128 may comprise any of the following materials: Au, Ti, Al, Ag, Rh, Ni, WO or intermetallic compounds. For example, the conductive material filled in the opening 125 may form a via contact 131 for contacting the first semiconductor layer 110. For example, the conductive layer 128 may be formed to have a thickness of approximately 1 to 2 μm.

Moreover, the filling material 130 may e.g. comprise nickel, or any other suitable conductive material. The solder layer 133 may comprise precious materials, e.g. Au, Sn, Pt and others. Generally, a thickness of the solder layer may be larger than 3 μm. Due to the specific configuration described, the thickness O the solder layer may be smaller than 3 μm, e.g. less than 1.5 μm. According to embodiments, the thickness of the solder layer may be even smaller than 1.5 μm, e.g. less than 200 nm.

Generally, for achieving a higher reflectivity and, hence, a higher brightness of the optoelectronic semiconductor device 10, the mirror 122 is made at a high thickness. For example, the thickness of the mirror may be 0.6 μm and larger, e.g. more than 1 μm. When the mirror 122 is formed at a large thickness, the opening 125 is formed to have a large diameter in order to contact a portion of the semiconductor layer stack 105, e.g. the first semiconductor layer 110. Forming the opening 125 at a large diameter results a large void 129 to be formed. If this void is to be filled with the solder material 133, it is necessary to form the solder layer 133 to have a comparatively large thickness. This makes the optoelectronic semiconductor device 10 expensive. Moreover, there is a risk of remaining voids 129 in the resulting optoelectronic semiconductor device 10. Due to the feature that the void 129 is filled with the filling material 130, there is no need to employ a solder layer 133 having a large thickness. For example, a surface of the filling material 130 may be flush with a surface of the conductive layer 128. According to further examples, a thin layer of the filling material 130 may be arranged over the surface of the workpiece. As a consequence, a planar surface of the workpiece may be achieved.

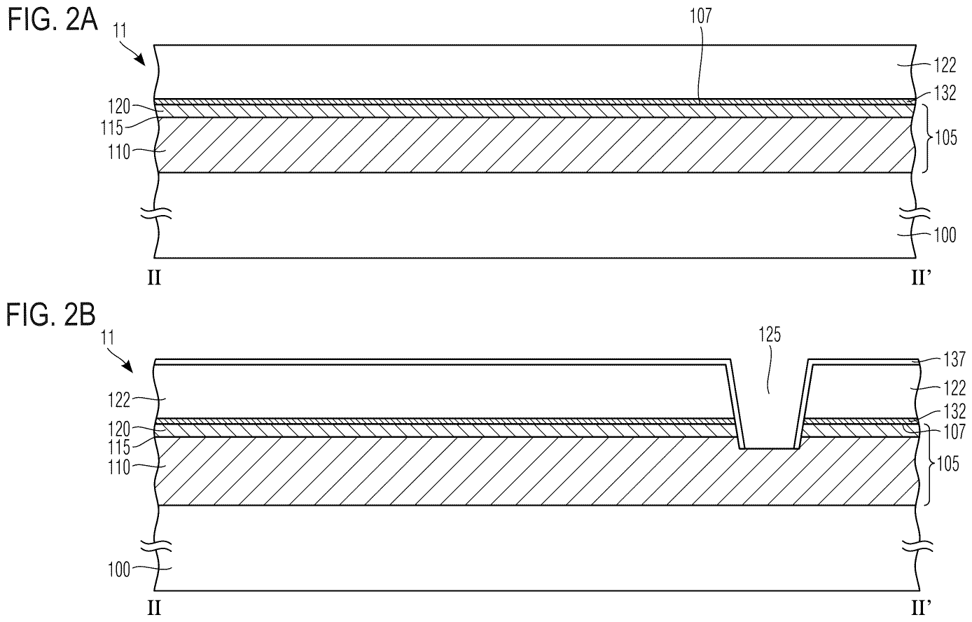

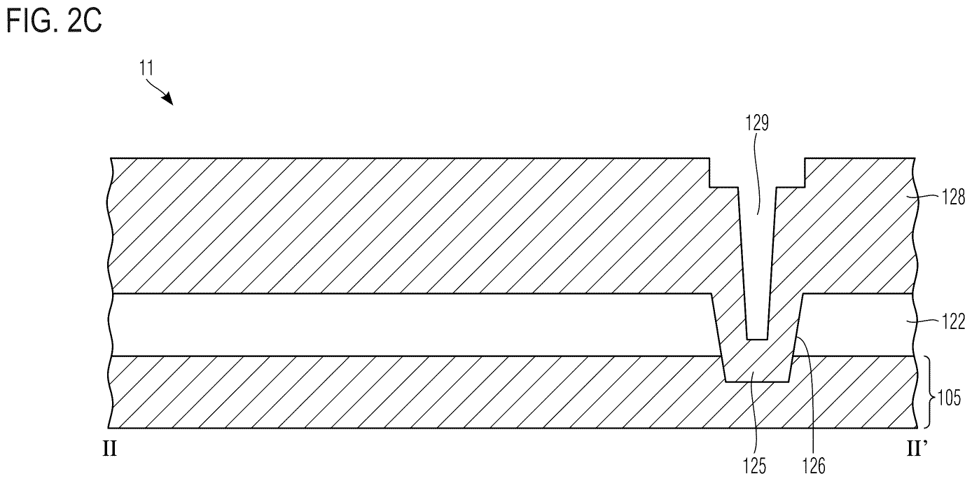

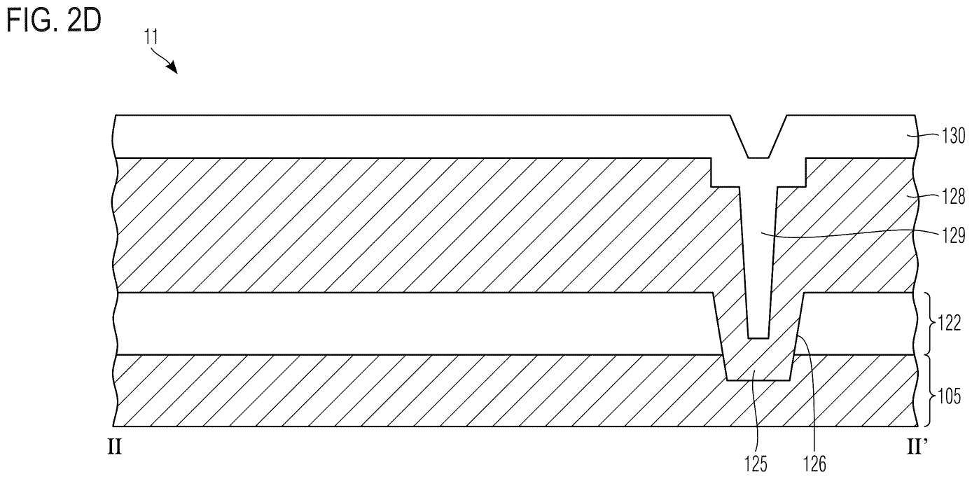

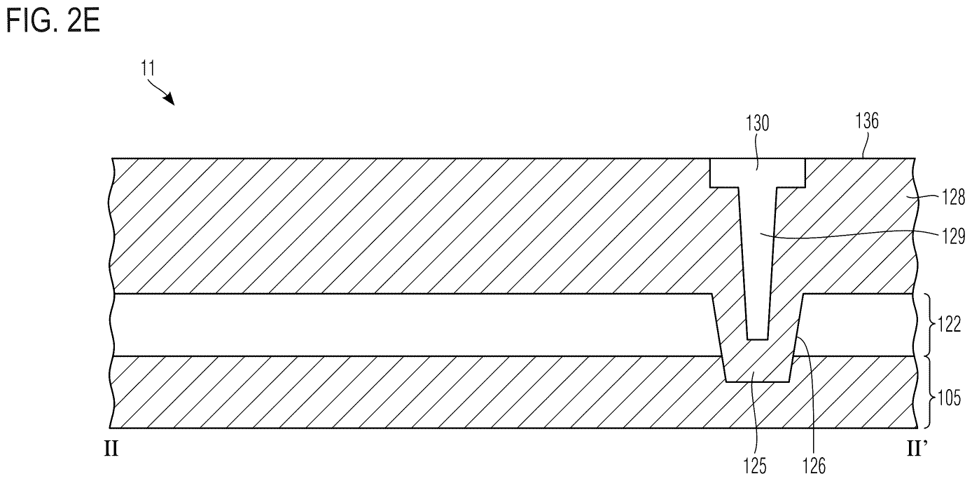

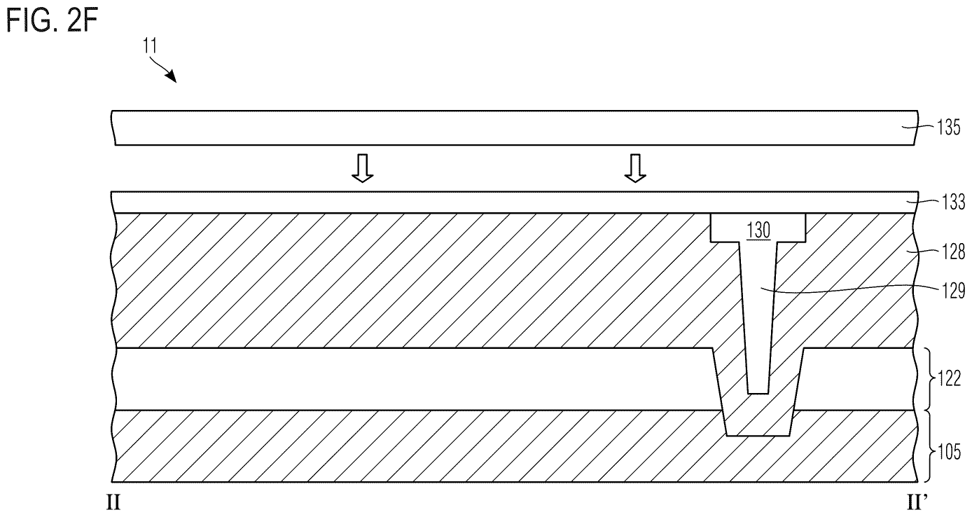

In the following, a method of manufacturing the optoelectronic semiconductor device 10 will be explained. Referring to FIG. 2A, a semiconductor layer stack 105 is epitaxially grown over a suitable growth substrate 100. For example, the first semiconductor layer 110 and the second semiconductor layer 120 and the active zone 115 may comprise GaN layers. The growth substrate may e.g. be a GaN substrate or a sapphire substrate. Further, a current spreading layer 132 may be formed in contact with the second semiconductor layer 120. Thereafter, the mirror 122 is formed over the first main surface 107 of the semiconductor layer stack 105. For example, as has been explained above, the mirror 122 may comprise dielectric layers and/or metal layers. FIG. 2A shows an example of a resulting workpiece 11.

Referring to FIG. 2B, openings 125 are formed in a surface of a resulting workpiece 11 and, in particular, in a first main surface 107 of the semiconductor layer stack 105. The opening 125 may extend to the first semiconductor layer 110. Further, an insulating passivation layer 137 is formed over a surface of the mirror 122 and over side faces of the openings 125. FIG. 2B shows an example of a resulting workpiece 11.

Referring to FIG. 2C, thereafter, a conductive layer 128 is formed over the resulting workpiece 11. In particular, the conductive layer 128 may be formed as a conformal layer so that the sidewalls 126 of the opening 125 are covered by the conductive layer 128. As is shown in FIG. 2C, after forming the conductive layer 128, the void 129 is formed. Depending on a thickness of the mirror 122, a horizontal and a vertical extension of the void 129 increase. FIG. 2C shows an example of a resulting workpiece 11. In the following Figures, the semiconductor layer stack 105 is schematically shown, without explicitly showing the single layers, e. g. the first and the second semiconductor layers 110, 120 in detail.

Thereafter, referring to FIG. 2D, a layer of a filling material 130 may be formed over a resulting surface. For example, the filling material 130 may be formed by a sputtering process. According to further embodiments, different processes that enable a filling of the void 129 may be employed. FIG. 2C shows an example of a resulting workpiece 11.

Thereafter, referring to FIG. 2E, the resulting surface may be planarized, e.g. using a CMP (“chemical-mechanical polishing”) method. As a result, a surface of the filling material may be flush with a main surface of the conductive layer. According to further implementations, a thin layer of the filling material 130 may remain over a surface of the workpiece 11. For example, a portion of the filling material 130 does not protrude from the surface of the workpiece 11. As a result, a second main surface 136 of the workpiece 11 may be planar. FIG. 2E shows an example of a resulting workpiece 11.

Then, a solder layer 133 is formed over the second main surface 136 of the workpiece 11. For example, a material of the solder layer 133 may comprise a precious material such as Au. Finally, a conductive carrier 135 is attached to the solder layer 133. Since the second main surface 135 of the workpiece 11 is planar, this may be accomplished using a solder bonding or direct bonding method. FIG. 2F shows an example of a resulting workpiece. Thereafter, the workpiece 11 may be singulated into single semiconductor chips.

FIG. 3A shows a top view of an optoelectronic semiconductor device 10 according to embodiments. As is shown, via contacts 131 having e.g. a circular cross-section are formed in a regular pattern. As is clearly to be understood, the pattern may also be different from a regular pattern. Further, the cross-section of the via contacts 131 may be different. At the edge portion, contacts to the second current spreading layer may be arranged.

FIG. 3B Shows an Example of a Cross-sectional View of the optoelectronic semiconductor device 10 according to embodiments. The cross-sectional view of FIG. 3B is taken between I and I′ so as to intersect a plurality of via contacts 131. As is shown, the generated electromagnetic radiation 15 is emitted via a surface of the first semiconductor layer 110. The semiconductor layer stack 105 comprising a first semiconductor layer 110, an active zone 115 and a second semiconductor layer 120 is arranged over a conductive carrier 135. A second current spreading layer 132 may be arranged in contact with the second semiconductor layer 120. A mirror 122 is arranged on a surface of the second current spreading layer 132 remote from the second semiconductor layer 120. The mirror 122 is formed over a side of the second semiconductor layer 120 facing away from the first semiconductor layer 110. Via contacts 131 are formed to extend to the first semiconductor layer 110. The via contacts 131 electrically contact the conductive layer 128 with the first semiconductor layer 110.

The carrier 135 is attached to the conductive layer 128 via a solder layer 133. For example, a filling material 130 may be arranged between the conductive layer 128 and the solder layer 133 in a region of a via contact 131.

For example, a first contact element 101 may be arranged adjacent to a surface of the conductive carrier 135 facing away from the semiconductor layer stack 105. The first contact element 101 may implement a back side contact. Moreover, a second contact element 102 may be arranged in an edge portion of the optoelectronic semiconductor device 10. The second contact element 102 may be electrically connected to the second current spreading layer 132.

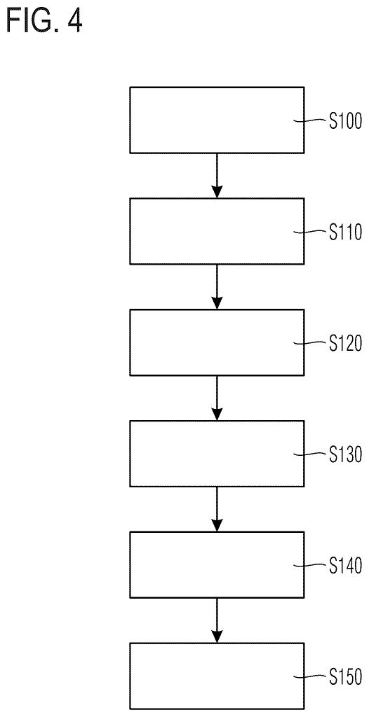

FIG. 4 summarizes a method according to embodiments. A method of manufacturing an optoelectronic semiconductor device may comprise forming (S100) a semiconductor layer stack configured to generate electromagnetic radiation and forming (S110) a mirror comprising dielectric layers over a first main surface of the semiconductor layer stack. The method further comprises forming (S120) an opening in the mirror, the opening extending from a first main surface of the mirror to a second main surface of the mirror, and forming (S130) a conductive layer over the first main surface of the mirror. The first main surface of the mirror is remote from the semiconductor layer stack. During this process, the conductive layer is formed Over sidewalls of the opening, thereby defining a void. The method further comprises forming (S140) a filling material filling the void, the filling material being different from the conductive layer and arranging (S150) a conductive carrier over the conductive layer.

As has been described, due to the presence of the filling material 130, it is possible to reduce the thickness of the solder layer 133. As a consequence, cost saving may be achieved since the amount of precious metal may be reduced.

Due to the presence of the filling material 130, it is possible to form the mirror layer 122 to have a large thickness. As a consequence, a higher degree of topography may be generated without the risk of forming voids or the need for a large thickness of the solder layer 133.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

### LIST OF REFERENCES

10 optoelectronic semiconductor device
11 workpiece
15 electromagnetic radiation
100 growth substrate
101 first contact element
102 second contact element
105 semiconductor layer stack
107 first main surface of semiconductor layer stack
110 first semiconductor layer
111 first dielectric layer
112 second dielectric layer
115 active zone
120 second semiconductor layer
122 mirror
123 first main surface of mirror
124 second surface of mirror
125 opening
126 sidewall of the opening
128 conductive layer
129 void
130 filling material
131 via contact
132 second current spreading layer
133 solder layer
135 conductive carrier
136 second main surface of workpiece
137 passivation layer

1. An optoelectronic semiconductor device comprising:
a semiconductor layer stack configured to generate electromagnetic radiation;
a mirror comprising horizontal dielectric layers, arranged over a first main surface of the semiconductor layer stack, an opening being formed in the mirror, the opening extending from a first main surface of the mirror to a second surface of the mirror, the first main surface of the mirror being remote from the semiconductor layer stack;
a conductive layer arranged over the first main surface of the mirror the conductive layer being arranged on sidewalls of the opening thereby defining a void, and being configured to electrically contact a portion of the semiconductor layer stack;
a filling material filling the void, the filling material being different from the conductive layer;
a solder layer over the filling material and over the conductive layer a material of the solder layer being different from the filling material; and
a conductive carrier over the solder layer.

2. The optoelectronic semiconductor device according to claim 1, wherein the semiconductor layer stack comprises a first semiconductor layer of a first conductivity type, an active zone, and a second semiconductor layer of a second conductivity type, wherein the second semiconductor layer is arranged on a side facing the mirror, and the conductive layer is configured to electrically contact the first semiconductor layer.

3. The optoelectronic semiconductor device according to claim 1, wherein a thickness of the mirror is larger than 500 nm.

4. The optoelectronic semiconductor device according to claim 1, wherein the filling material comprises a conductive material.

5. The optoelectronic semiconductor device according to claim 1, wherein a surface of the filling material is flush with a main surface of the conductive layer.

6. The optoelectronic semiconductor device according to claim 2, further comprising a second current spreading layer in contact with the second semiconductor layer.

7. The optoelectronic semiconductor device according to claim 1, wherein a thickness of the solder layer is less than 1.5 μm.

8. A method of manufacturing an optoelectronic semiconductor device, the method comprising:
forming a semiconductor layer stack configured to generate electromagnetic radiation;
forming a mirror comprising horizontal dielectric layers, over a first main surface of the semiconductor layer stack;
forming an opening in the mirror, the opening extending from a first main surface of the mirror to a second main surface of the mirror;
forming a conductive layer over the first main surface of the mirror the first main surface of the mirror being remote from the semiconductor layer stack, comprising forming the conductive layer over sidewalls of the opening, thereby defining a void;
forming a filling material filling the void, the filling material being different from the conductive layer;
forming a solder layer over the filling material and over the conductive layer, a material of the solder layer being different from the filling material; and
arranging a conductive carrier over the solder layer.

9. The method according to claim 8, wherein the solder layer is formed to have a thickness less than 1.5 μm.

10. The method according to claim 8, further comprising planarizing a second main surface of a resulting workpiece before forming the solder layer.

11. The method according to claim 8, wherein the conductive carrier is arranged over the solder layer using a direct bonding method.
